(19) United States
(12) Patent Application Publication
(10) Pub. No.: US 2011/0101318 A1
(43) Pub. Date: May 5, 2011

(54) NOVEL MACROMOLECULAR COMPOUNDS HAVING A CORE-SHELL STRUCTURE FOR USE AS SEMICONDUCTORS

(76) Inventors: Timo Meyer-Friedrichsen, Krefeld (DE); Stephan Kirchmeyer, Leverkusen (DE); Andreas Elschner, Mulheim (DE); Sergei Ponomarenko, Moskau (RU)

(21) Appl. No.: 12/922,591

(22) PCT Filed: Feb. 10, 2009
(86) PCT No.: PCT/EP2009/051482

§ 371 Date: Jan. 13, 2011

(30) Foreign Application Priority Data
Mar. 14, 2008 (DE) 102008014158.5

(51) Int. Cl. H01L 51/54; C07F 7/08; C07F 7/10; H01L 51/56

(52) U.S. Cl. 257/40; 549/4; 438/99; 257/E51.041

(57) ABSTRACT

The invention relates to novel macromolecular compounds having a core-shell structure and also their use in electronic components.

The invention relates to novel macromolecular compounds having a core-shell structure and also their use in electronic components.

The field of molecular electronics has developed rapidly in the last 15 years with the discovery of organic conductive and semiconducting compounds. In this time, many compounds which have semiconducting or electrooptical properties have been found. It is generally understood that molecular electronics will not displace conventional semiconductor building blocks based on silicon. Instead, it is assumed that molecular electronic components will open up new fields of application in which suitability for coating large areas, structural flexibility, processability at low temperatures and low costs are required. Semiconducting organic compounds are at present being developed for fields of application such as field effect transistors (OFETs), organic light-emitting diodes (OLEDs), sensors and photovoltaic elements. Simple structuring and integration of OFETs into integrated organic semiconductor circuits provides inexpensive solutions for smart cards or price displays which have hitherto not been able to be achieved by means of silicon technology because of the price and lack of flexibility of the silicon building blocks. OFETs can likewise be used as switching elements in large-area flexible matrix displays. An overview of organic semiconductors, integrated semiconductor circuits and their applications is given, for example, in H. Klauk (editor), Organic Electronics, Materials, Manufacturing and Applications, Wiley-VCH 2006.

A field effect transistor is a three-electrode element in which the conductivity of a thin conduction channel between two electrodes (known as “source” and “drain”) is controlled by means of a third electrode (known as “gate”) which is separated from the conduction channel by means of a thin insulating layer. The most important characteristic properties of a field effect transistor are the mobility of the charge carriers which decisively determines the switching speed of the transistor and the ratio between the currents in the switched and unswitched state, known as the “on/off ratio”.

Two large classes of compounds have hitherto been used in organic field effect transistors. Compounds of both classes have extended conjugated units and are divided according to molecular weight and structure into conjugated polymers and conjugated oligomers.

Oligomers generally have a uniform molecular structure and a molecular weight below 10 000 dalton. Polymers generally comprise chains of uniform repeating units having a molecular weight distribution. However, there is a fluid transition between oligomers and polymers.

The distinction between oligomers and polymers is frequently reflected in that there is a fundamental difference in the processing of these compounds. Oligomers are frequently vaporizable and are applied to substrates by vapour deposition processes. The term polymers is frequently used to refer, independently of their molecular structure, to compounds which are no longer vaporizable and are therefore applied by other methods. In the case of polymers, compounds which are soluble in a liquid medium, for example organic solvents, and can then be applied by appropriate application methods are generally sought. A very widespread application method is, for example, spin coating. A particularly elegant method is application of semiconducting compounds by the ink jet process. In this process, a solution of the semiconducting compound is applied to the substrate in the form of very fine droplets and dried. This process allows structuring to be carried out during application. A description of this application process for semiconducting compounds is described, for example, in Nature, volume 401, page 685.

In general, wet-chemical processes are considered to have a greater potential for arriving at inexpensive organic integrated semiconductor circuits in a simple way.

An important prerequisite for the production of high-quality organic semiconductor circuits is compounds having an extremely high purity. In semiconductors, ordering phenomena play a large role. Hindering of a uniform alignment of compounds and pronounced grain boundaries lead to a dramatic drop in the semiconducting properties, so that organic semiconductor circuits which have been constructed using compounds which are not of extremely high purity are generally unusable. Remaining impurities can, for example, inject charges into the semiconducting compound (“doping”) and thus reduce the on/off ratio or serve as charge traps and thus drastically reduce the mobility. Furthermore, impurities can initiate the reaction of semiconducting compounds with oxygen and impurities having an oxidizing action can oxidize the semiconducting compounds and thus shorten possible storage, processing and operating times.

The purity which is generally required is so high that it can generally not be achieved by the known polymer-chemical processes such as washing, reprecipitation and extraction. On the other hand, oligomers can, as molecularly uniform and frequently volatile compounds, be purified relatively simply by sublimation or chromatography.

Some important representatives of semiconducting polymers are described below. In the case of polyfluorenes and fluoroene copolymers, for example poly(9,9-dioctylfluorene-co-bithiophene) (I)

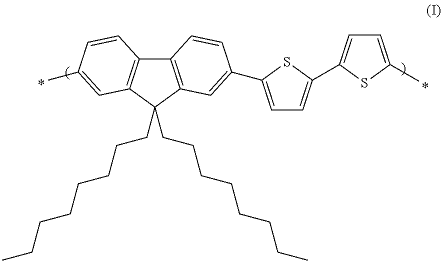

charge mobilities, hereinafter also referred to as mobilities for short, of up to 0.02 cm²/Vs have been achieved (Science, 2000, volume 290, page 2123), while in the case of regioregular poly(3-hexylthiophene-2,5-diyl) (II)

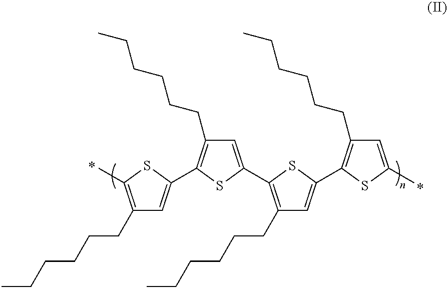

mobilities of up to 0.1 cm²/Vs have been achieved (Science, 1998, volume 280, page 1741). Polyfluorene, polyfluorene copolymers and poly(3-hexylthiophene-2,5-diyl) form, like virtually all long-chain polymers, good films after application from solution and are therefore easy to process. However, as high molecular weight polymers having a molecular weight distribution, they cannot be purified by vacuum sublimation and are difficult to process by chromatography.

The important representatives of oligomeric semiconducting compounds are, for example, oligothiophenes, in particular those having terminal alkyl substituents as per formula (III)

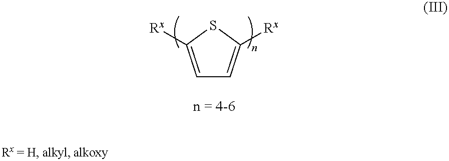

and pentacene (IV)

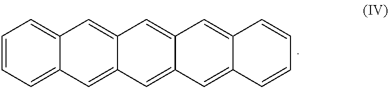

Typical mobilities for, for example, α,α′-dihexylquarterthiophene, -quinquethiophene and -sexithiophene are in the range 0.05-0.1 cm²/Vs. Oligothiophenes are generally hole semiconductors, i.e. it is exclusively positive charge carriers which are transported.

The highest mobilities of a compound are obtained in single crystals, e.g. a mobility of 1.1 cm²/Vs for single crystals of α,α′-sexithiophene (Science, 2000, volume 290, page 963) and 4.6 cm²/Vs for rubrene single crystals (Adv. Mater., 2006, volume 18, page 2320) has been described. If oligomers are applied from solution, the mobilities usually decrease sharply. In general, the decrease in the semiconducting properties when oligomeric compounds are processed from solution is attributed to the moderate solubility and low film formation tendency of the oligomeric compounds. Thus, inhomogeneities are attributed, for example, to precipitates formed during drying of the solution (Chem. Mater., 1998, volume 10, page 633).

Attempts have therefore been made to combine the good processing and film formation properties of semiconducting polymers with the properties of semiconducting oligomers. U.S. Pat. No. 6,025,462 describes conductive polymers which have a star structure and comprise a branched core and a shell of conjugated side groups. However, these have some disadvantages. If the side groups are formed by laterally unsubstituted conjugated structures, the resulting compounds are sparingly soluble or insoluble and cannot be processed. If the conjugated units are substituted by side groups, this does lead to improved solubility but the side groups cause, due to their bulk, internal disorder and morphological defects which impair the semiconducting properties of these compounds.

WO 02/26859 A1 describes polymers comprising a conjugated backbone to which aromatic conjugated chains are attached. The polymers bear diarylamine side groups which make electronic conduction possible. However, these compounds are unsuitable as semiconductors because of the diarylamine side groups.

EP-A 1 398 341 and EP-A 1 580 217 describe semiconducting compounds which have a core-shell structure and are used as semiconductors in electronic components and can be processed from solution. However, these compounds tend to give films which do not crystallize readily during production, which can be a hindrance for some applications because crystallized films are a prerequisite for high charge carrier mobility. Although it is known that films of organic semiconductors can be subsequently ordered by heat treatment (deLeeuw et. al. WO 2005104265), the macromolecular character of the compound can also hinder complete subsequent organization by heat treatment.

In Applied Physics Letters 90, 053504 (2007), Jang et al. describe the production of transistors by ink-jet printing processes. α,α′-Dihexylquarterthiophene was used as organic semiconductor. The mobilities found here of 0.043 cm²/Vs correspond to those of vapour-deposited layers of the material. However, very small electrode spacings in the transistor of 6 μm were selected. Such small structures cannot be produced in a roll-to-roll mass printing process. Modern printing processes at present achieve resolutions of about 20-50 μm. At these spacings, homogeneity and phase boundaries in the semiconducting layer play a significantly greater role.

Appl. Phys. Lett. 87, 222109 (2005), Russel et al. describe the use of mixtures of poly(3-hexylthiophene-2,5-diyl) and α,α′-dihexylquarterthiophene for semiconducting layers in organic field effect transistors. Here, the α,α′-dihexylquarterthiophene forms crystalline islands which are connected by the polymer. However, the mobilities found in the semiconducting is layer are limited by the low mobilities of poly(3-hexylthiophene-2,5-diyl) compared to α,α′-dihexylquarterthiophene. In Jap. J. Appl. Phys. (2005), volume 44, page L1567, mixtures of poly(3-hexylthiophene-2,5-diyl) and α,α′-dihexylsexithiophene are used for producing field effect transistors. However, to achieve sufficient solubility of the compounds, the solutions have to be heated to 190° C., which is unsuitable for an industrial application. Adv. Funct. Mater. 2007, 17, 1617-1622 describes a cyclohexyl-substituted quarterthiophene which crystallizes from saturated solutions. However, this type of processing does not allow mass production. In addition, small channel lengths have to be used in the electrode structure in order to ensure that the crystallites have sufficient overlap over these structures. The production of such small electrode structures once again requires complicated lithographic processes which cannot be used in a fast printing process for mass production.

There is therefore a need for semiconductors which have improved properties after processing from solvents.

It is an object of the invention to provide organic compounds which can be processed from customary solvents, give semiconducting films having good properties and remain sufficiently stable on storage in the air. Such compounds would be highly suitable for the large-area application of organic semiconducting layers.

It would, in particular, be desirable for the compounds to form high-quality layers of uniform thickness and morphology and be suitable for electronic applications.

It has surprisingly been found that organic compounds have the desired properties when they have a core-shell structure comprising a core made up of multifunctional units and a shell composed of connecting chains and linear conjugated oligomeric chains which are each capped at the terminal linkage point via at least one methylene carbon atom bearing an electron-withdrawing group by at least one flexible nonconjugated chain.

In particular, the film morphology and the resulting macroscopic electrical properties of the films composed of oligomeric organic compounds and mixtures thereof with macromolecular compounds having a core-shell structure and/or compounds with monomeric linear compounds are improved compared to semiconductors composed of pure monomeric linear compounds or of pure macromolecular compounds having a core-shell structure.

The invention provides macromolecular compounds having a core-shell structure, wherein the core has a macromolecular base structure based on silicon and/or carbon and is joined to at least two carbon-based linear oligomeric chains having continuously conjugated double bonds via a connecting chain based on carbon and the linear conjugated chains are each capped via at least one methylene carbon atom bearing an electron-withdrawing group by at least one further, in particular aliphatic, araliphatic or oxyaliphatic chain without conjugated double bonds.

The organic macromolecular compounds having a core-shell structure can, in a preferred embodiment, be oligomers or polymers. For the purposes of the invention, oligomers are compounds having a molecular weight below 1000 Dalton and polymers are compounds having an average molecular weight of 1000 Dalton and above. The average molecular weight can be, depending on the measurement method, the number average molecular weight (Mₙ) or weight average molecular weight (M_{w}). Here, it is the number average molecular weight (Mₙ) which is referred to.

For the purposes of the invention, the core-shell structure is a structure on a molecular level, i.e. it relates to the structure of one molecule.

The terminal linkage point of the linear conjugated oligomeric chain is, for the present purposes, the point in the terminal unit of the linear oligomeric chain having conjugated double bonds via which no further linkage to a further such chain occurs. Terminal means farthest removed from the core. The linear oligomeric chain having continuously conjugated double bonds will hereinafter also be referred to as linear conjugated oligomeric chain for short.

The macromolecular compounds having a core-shell structure preferably have a core-shell structure of the general formula (Z),

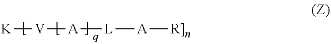

where
K is an n-functional core,
V is a connecting chain,
L is a linear conjugated oligomeric chain, preferably one comprising optionally substituted thiophene or phenylene units,
A is a methylene carbon atom bearing electron-withdrawing groups which is selected from the group consisting of carbonyl, dicyanovinyl, cyanoacrylic esters, malonic esters or dihalomethylene,
R stands for linear or branched C₂-C₂₀-alkyl radicals, C₃-C₈ cycloalkylene radicals, monounsaturated or polyunsaturated C₂-C₂₀-alkenyl radicals, C₂-C₂₀-alkoxy radicals, C₂-C₂₀-aralkyl radicals or C₂-C₂₀-oligoether or C₂-C₂₀-polyether radicals,
q is 0 or 1 and
n is an integer greater than or equal to 2, preferably a number between 2 and 4.

When the electron-withdrawing group on A forms a cyanoacrylic ester or a malonic ester, the corresponding alkyl radical is a linear or branched C₁-C₁₂-alkyl radical, preferably a linear or branched C₁-C₈-alkyl radical. When the electron-withdrawing group on A forms a dihalomethylene group, this is a dibromomethylene, dichloromethylene, diiodomethylene or difluoromethylene group, preferably a difluoromethylene group.

The shell of the preferred compounds is formed by the n-V-(A)_{q}⁻L-A-R building blocks which are each attached to the core.

In the case of, for example, n equals 3, 4 or 6, these are structures of the formulae (Z-3), (Z-4) or (Z-6)

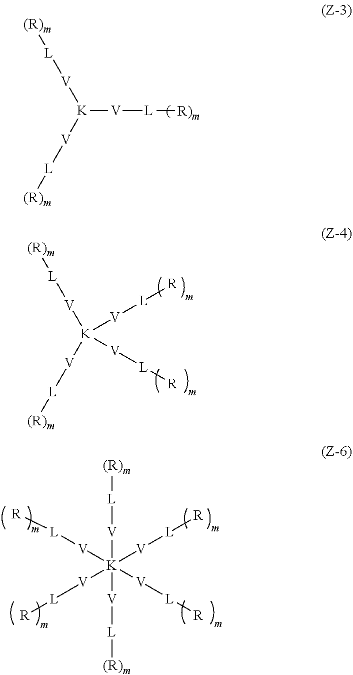

where K, V, L and R are as defined above.

Such compounds are constructed so that a core made up of multifunctional units, i.e. a branched core, connecting chains, methylene carbon atom(s) bearing electron-withdrawing groups, linear conjugated oligomeric chains and nonconjugated chains are joined to one another.

The core made up of multifunctional units preferably has dendritic or hyperbranched structures.

Hyperbranched structures and their preparation are known per se to those skilled in the art. Hyperbranched polymers or oligomers have a particular structure which is predetermined by the structure of the monomers used. Monomers used are ABn monomers, i.e. monomers which bear two different functions A and B. Of these, one function (A) occurs only once per molecule, while the other function (B) occurs a number of times (n times). The two functions A and B can be reacted with one another to form a chemical bond, e.g. be polymerized. Owing to the monomer structure, polymers having a tree-like structure, known as hyperbranched polymers, are formed on polymerization. Hyperbranched polymers do not have regular branching points, have no rings and have virtually exclusively B functions at the ends of the chains. Hyperbranched polymers, their structure, the question of branching and their nomenclature is described for the example of hyperbranched polymers based on silicones in L. J. Mathias, T. W. Carothers, Adv. Dendritic Macromol. (1995), 2, 101-121, and the studies cited therein.

For the purposes of the invention, the hyperbranched structures are preferably dendritic polymers.

For the purposes of the invention, dendritic structures are synthetic macromolecular structures which are built up stepwise by joining two or more monomers onto each previously bound monomer, so that the number of monomer end groups increases exponentially with each step and a spherical tree structure is formed in the end. In this way, three-dimensional, macromolecular structures having groups which have branching points and continue from a centre to the periphery in a regular fashion. Such structures are usually built up layer-by-layer by methods known to those skilled in the art. The number of layers is usually referred to as the number of generations. The number of branches in each layer and the number of terminal groups increase with increasing generation. Owing to their regular structure, dendritic structures can offer particular advantages. Dendritic structures, methods of preparation and nomenclature are known to those skilled in the art and are described, for example, in G. R. Newkome et. al., Dendrimers and Dendrons, Wiley-VCH, Weinheim, 2001.

The structures which can be used in the core made up of dendritic or hyperbranched structures, hereinafter also referred to as dendritic or hyperbranched core for short, are, for example, those described in U.S. Pat. No. 6,025,462. These are, for example, hyperbranched structures such as polyphenylenes, polyether ketones, polyesters as described, for example, in U.S. Pat. No. 5,183,862, U.S. Pat. No. 5,225,522 and U.S. Pat. No. 5,270,402, aramids as described, for example, in U.S. Pat. No. 5,264,543, polyamides as described in U.S. Pat. No. 5,346,984, polycarbosilanes or polycarbosiloxanes as described, for example, in U.S. Pat. No. 6,384,172 or polyarylenes as described, for example, in U.S. Pat. No. 5,070,183 or U.S. Pat. No. 5,145,930 or dendritic structures such as polyarylenes, polyarylene ethers or polyamidoamines as described, for example, in U.S. Pat. No. 4,435,548 and U.S. Pat. No. 4,507,466 and also polyethylenimines as described, for example, in U.S. Pat. No. 4,631,337.

A dendritic core is preferably formed by siloxane and/or carbosilane units. As siloxane units, preference is given to use disiloxane and tetramethyldisiloxane units, and preferred carbosilane units are tetrapropylenesilane, tetraethylenesilane, methyltripropylenesilane, ethyltripropylenesilane, propyltripropylenesilane, hexyltripropylenesilane, dimethyldipropylenesilane, diethyldipropylenesilane, dipropyldipropylenesilane, dihexyldipropylenesilane, hexylmethyldipropylenesilane units. However, it is also possible to use other structural units for building up the dendritic or hyperbranched core. The role of the dendritic or hyperbranched core is predominantly to make available a series of functions and thus form a matrix to which the connecting chains with the linear conjugated oligomeric chains can be attached and thus be arranged in a core-shell structure. The linear conjugated oligomeric chains are preordered by attachment to the matrix and thus increase their effectiveness.

The dendritic or hyperbranched core has a number of frontal groups (functions), in the sense of linkage points, which are suitable for attachment of the connecting chains with the linear conjugated oligomeric chains. In particular, the dendritic core has, like the core made up of hyperbranched structures, at least two but preferably at least three functions, particularly preferably at least four functions.

Preferred structures in the dendritic or hyperbranched core are 1,3,5-phenylene units (formula V-a) and units of the formulae (V-b) to (V-e), with a plurality of identical or different units of the formulae (V-a) to (V-e) being bound to one another,

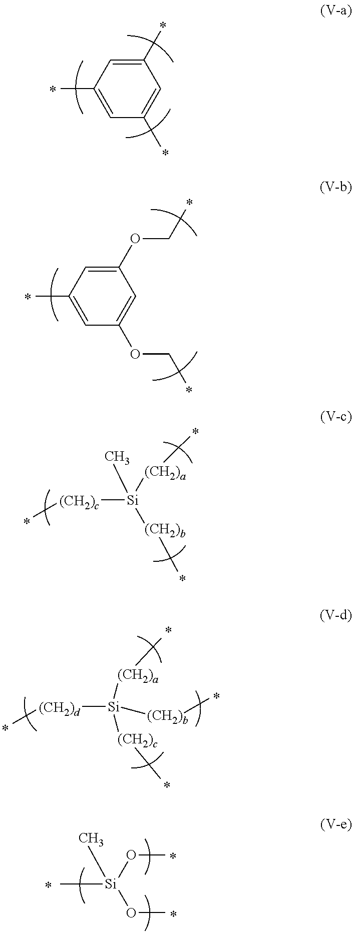

where a, b, c and d in the units of the formulae (V-c) and (V-d) are each, independently of one another, 0, 1, 2 or 3.

The positions denoted by * in the formulae (V-a) to (V-e) and in further formulae used below denote the linkage points. Via these, the units (V-a) to (V-e) are joined to one another or via the connecting chains and via, if appropriate, a methylene carbon atom bearing an electron-withdrawing group to the linear conjugated oligomeric chains (L).

Examples of dendritic cores (K) made up of units of the formula (V-a) are the following:

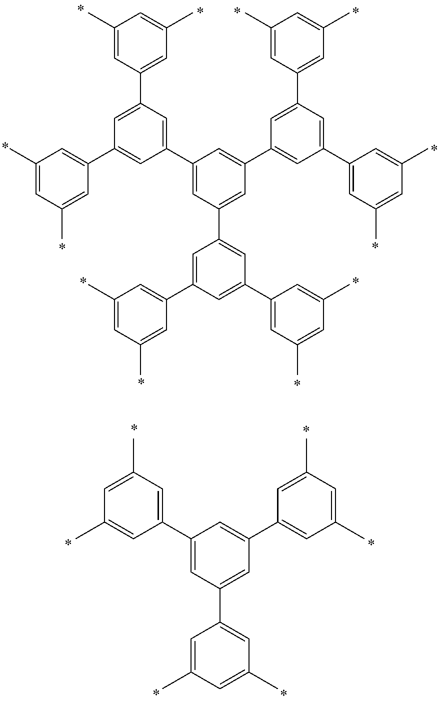

Linkage via the connecting chains (V) and, if appropriate, a methylene carbon atom (A) bearing an electron-withdrawing group to the linear conjugated oligomeric chains (L) occurs at the positions denoted by *.

The shell of the macromolecular compounds having a core-shell structure is formed by connecting chains (V), at least one methylene carbon atom (A) bearing an electron-withdrawing group, linear conjugated oligomeric chains (L) and the nonconjugated chains (R). Connecting chains (V) are preferably ones which have a high flexibility, i.e. a high (intra)molecular mobility, and in this way bring about a geometric anangement of the segments -L-R around the core K. For the purposes of the invention, flexible is meant in the sense of (intra)molecularly movable.

Suitable connecting chains are in principle linear or branched chains which have the following structural features:
carbon atoms bound by single bonds to carbon atoms,
hydrogen atoms bound to carbon,
oxygen atoms bound to carbon via single bonds,
silicon atoms bound to carbon via single bonds and/or
silicon atoms bound to oxygen via single bonds,
   which are preferably made up of a total of from 6 to 60 atoms and preferably do not contain any ring structures.

Suitable connecting chains are particularly preferably linear or branched C₂-C₂₀-alkylene chains such as ethylene, n-butylene, n-hexylene, n-octylene and n-dodecylene chains, linear or branched polyoxyalkylene chains, e.g. oligoether chains containing —OCH₂—, —OCH(CH₃)— or —O—(CH₂)₄-segments, linear or branched siloxane chains, for example those having dimethylsiloxane structural units, and/or straight-chain or branched carbosilane chains, i.e. chains containing silicon-carbon single bonds, with the silicon atoms and the carbon atoms being able to be arranged alternately, randomly or in blocks in the chains, e.g. chains having —SiR₂—CH₂—CH₂—CH₂—SiR₂— structural units.

Suitable linear conjugated oligomeric chains (L) of the general formula (Z) are in principle all chains which have structures which as such form electrically conductive or semiconducting oligomers or polymers. These are, for example, substituted or unsubstituted polyanilines, polythiophenes, polyethylenedioxythiophenes, polyphenylenes, polypyrroles, polyacetylenes, polyisonaphthenes, polyphenylene-vinylenes, polyfluorenes, which can be used as homopolymers or homooligomers or as copolymers or cooligomers. Examples of such structures which can preferably be used as linear conjugated oligomeric chains are chains composed of from 2 to 10, particularly preferably from 2 to 8, units of the general formulae (VI-a) to (VI-f),

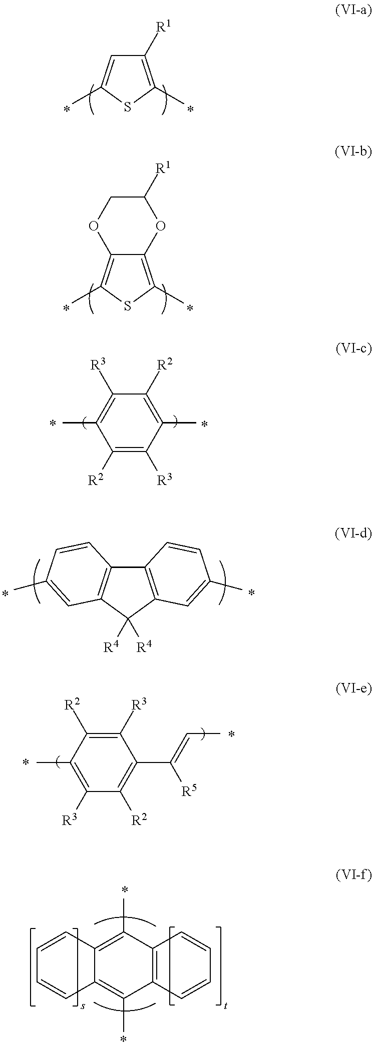

where
R¹, R² and R³ can be identical or different and are each hydrogen or a straight-chain or branched C₁-C₂₀-alkyl or C₁-C₂₀-alkoxy group and are preferably identical and each hydrogen,
the radicals R⁴ can be identical or different and are each hydrogen or a straight-chain or branched C₁-C₂₀-alkyl group or C₁-C₂₀-alkoxy group, preferably hydrogen or a C₆-C₁₂-alkyl group, and
R⁵ is hydrogen or a methyl or ethyl group, preferably hydrogen, and
s, t are each, independently of one another, an integer from 0 to 4 and s+t≧3, preferably s+t=4.

The positions denoted by * in the formulae (V-a) to (V-f) denote the linkage points via which the units (V-a) to (V-f) are joined to the linear conjugated oligomeric chain or bear, at the respective chain ends, the nonconjugated chains (R).

Particular preference is given to linear conjugated oligomeric chains which comprise units of substituted or unsubstituted 2,5-thiophenes (VI-a) or (VI-b) or substituted or unsubstituted 1,4-phenylenes (VI-c). The prefix numbers 2,5- or 1,4-indicate the positions in the units via which bonding occurs.

Here and in the following, substituted means, unless indicated otherwise, substitution by alkyl groups, in particular C₁-C₂₀-alkyl groups or by alkoxy groups, in particular C₁-C₂₀-alkoxy groups.

Very particular preference is given to linear conjugated oligomeric chains comprising units of substituted or unsubstituted 2,5-thiophenes (VI-a) or 2,5-(3,4-ethylenedioxythiophenes) (VI-b).

The linear conjugated oligomeric chains, denoted by L in the general formula (Z), are capped at each of the terminal linkage points by a nonconjugated chain (R). Nonconjugated chains are preferably ones which have a high flexibility, i.e. a high (intra)molecular mobility, and therefore interact readily with solvent molecules and thus produce improved solubility. For the purposes of the invention, the term flexible is used in the sense of having (intra)molecular mobility. The nonconjugated chains (R) are straight-chain or branched aliphatic, unsaturated or araliphatic chains which have from 2 to 20 carbon atoms, preferably from 6 to 20 carbon atoms, and may optionally be interrupted by oxygen, or C₃-C₈-cycloalkylenes. Preference is given to aliphatic and oxyaliphatic groups, i.e. alkoxy groups or straight-chain or branched aliphatic groups interrupted by oxygen, e.g. oligoether or polyether groups, or C₃-C₈-cycloalkylenes. Particular preference is given to unbranched C₂-C₂₀-alkyl or C₂-C₂₀-alkoxy groups or C₃-C₈-cycloalkylenes. Examples of suitable chains are alkyl groups such as n-hexyl, n-heptyl, n-octyl, n-nonyl, n-decyl and n-dodecyl groups and also alkoxy groups such as n-hexyloxy, n-heptyloxy, n-octyloxy, n-nonyloxy-, n-decyloxy and n-dodecyloxy groups or C₃-C₈-cycloalkylenes such as cyclopentyl, cyclohexyl or cycloheptyl.

As examples of structural elements -(A)_{q}-L-A-R in the general formula (Z) comprising linear conjugated oligomeric chains which are capped at each of the terminal linkage points by a nonconjugated chain, mention may be made of structural elements of the general formulae (VI-a-R) and (VI-b-R):

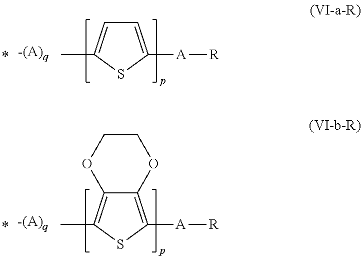

where A, R and q are as defined above for the general formula (Z) and
p is an integer from 2 to 10, preferably from 2 to 8, particularly preferably from 2 to 7.

Preferred embodiments of the macromolecular compounds having a core-shell structure are core-shell structures which comprise siloxane and/or carbosilane units in the dendritic core, linear, unbranched alkylene groups as connecting chain, carbonyl, dicyanovinyl, cyanoacrylic ester, malonic ester or dihalogenmethylene as electron-withdrawing groups of the at least one methylene carbon atom bearing an electron-withdrawing group, unsubstituted oligothiophene chains and/or oligo(3,4-ethylenedioxythiophene) chains having from 2 to 8, preferably from 4 to 6, substituted or unsubstituted thiophene or 3,4-ethylenedioxythiophene units as linear conjugated oligomeric chains and C₆-C₁₂-alkyl groups as flexible nonconjugated chains.

Examples of these are the following compounds of the formulae (Z-2-a) to (Z-2-i):

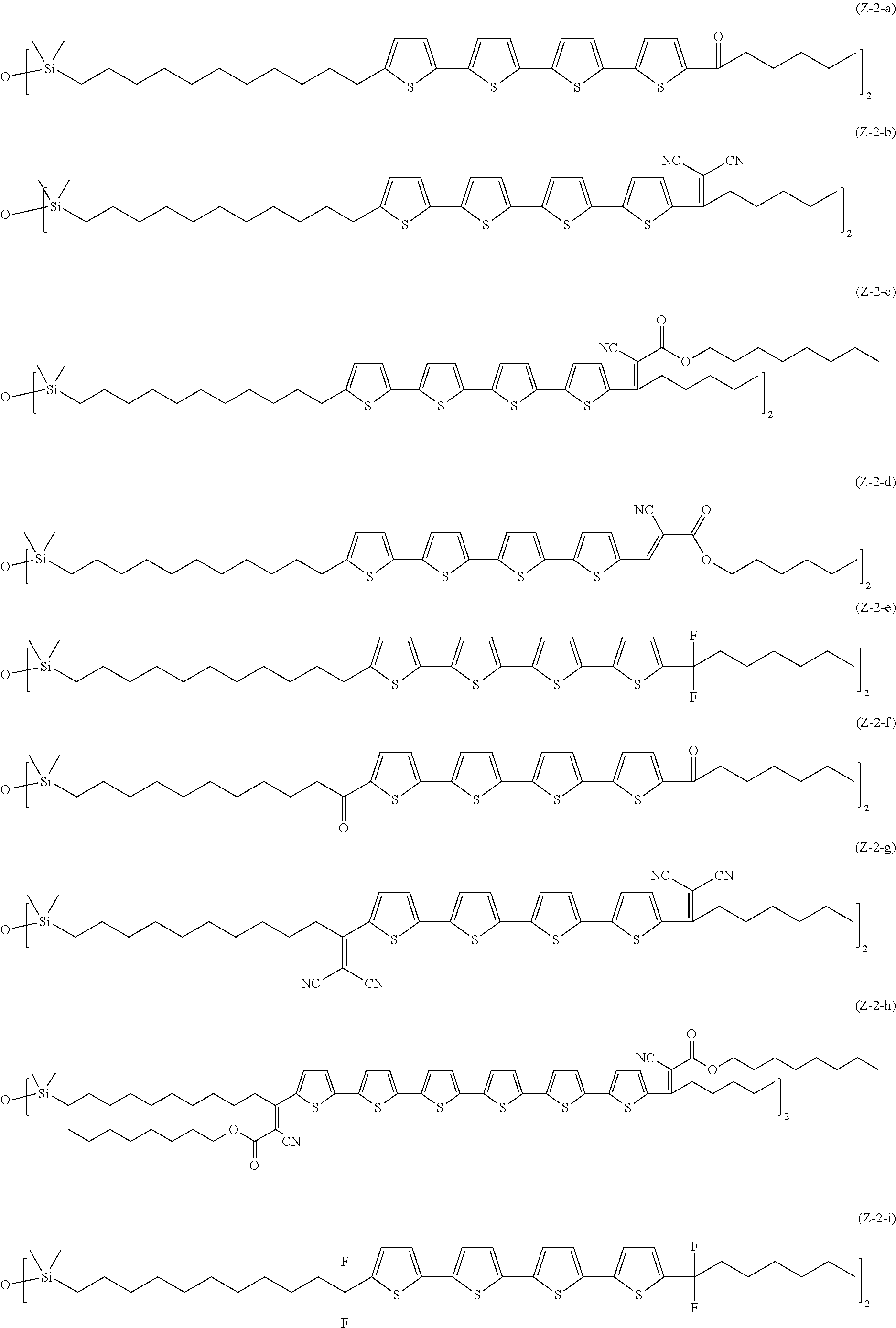

As further examples, mention may be made of the following compounds (Z-4-a) to (Z-4-h):

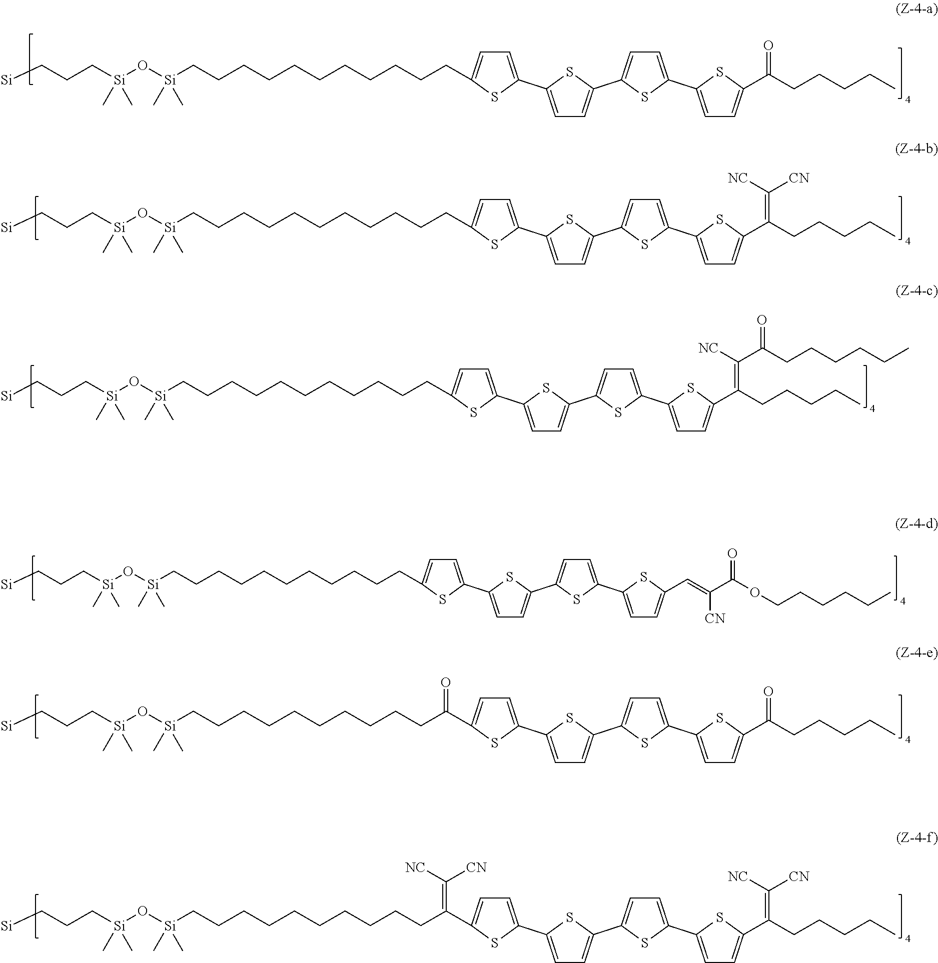

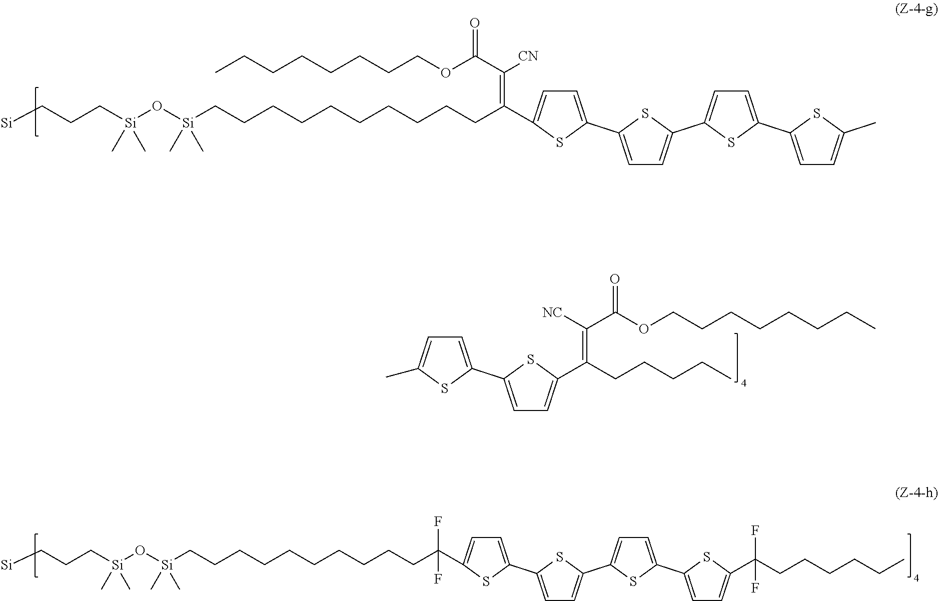

Layers of the macromolecular compounds according to the invention of the general formula (Z) are preferably conductive or semiconducting. Layers of the compounds or mixtures which are semiconducting are a particularly preferred subject matter of the invention. Particular preference is given to layers of the compounds which have a charge carrier mobility of at least 10⁻⁴ cm²/Vs. Charge carriers are, for example, positive holes.

The compounds of the invention are typically readily soluble in customary organic solvents and are therefore very suitable for processing from solution. Particularly suitable solvents are aromatics, ethers or halogenated aliphatic hydrocarbons, for example chloroform, toluene, benzene, xylenes, diethyl ether, dichloromethane, chlorobenzene, dichlorobenzene or tetrahydrofuran, or mixtures of these. The compounds of the invention can be prepared by various process routes.

The route by which the compounds of the invention are prepared is unimportant for the properties of the compounds.

The compounds of the invention have solubilities in customary solvents such as aromatics, ethers or halogenated aliphatic hydrocarbons, e.g. in chloroform, toluene, benzene, xylenes, diethyl ether, dichloromethane, chlorobenzene, dichlorobenzene or tetrahydrofuran, of at least 0.1% by weight, preferably at least 1% by weight, particularly preferably at least 5% by weight.

The compounds of the invention form high-quality layers having a uniform thickness and morphology from evaporated solutions and they are therefore suitable for electronic applications.

Finally, the invention further provides for the use of the compounds of the invention as semiconductors in electronic components such as field effect transistors, light-emitting components such as organic light-emitting diodes or photovoltaic cells, lasers and sensors.

The compounds of the invention are preferably used in the form of layers for these purposes.

To be able to ensure effective functionality as semiconductor, the compounds and mixtures of the invention have a sufficient mobility, e.g. at least 10⁻⁴ cm²/Vs. Charge mobilities can, for example, be determined as described in M. Pope and C. E. Swenberg, Electronic Processes in Organic Crystals and Polymers, 2nd ed., pages 709-713 (Oxford University Press, New York Oxford 1999).

For use, the compounds of the invention are applied to suitable substrates, for example to silicon wafers provided with electrical or electronic structures, polymer films or glass plates. All application methods are in principle possible for application. The compounds and mixtures of the invention are preferably applied from the liquid phase, i.e. from solution, and the solvent is subsequently evaporated. Application from solution can be effected by known methods, for example by spraying, dipping, printing and doctor blade coating. Particular preference is given to application by spin coating and by ink jet printing.

The layers produced from the compounds of the invention can be modified further after application, for example by means of heat treatment, e.g. involving a transient liquid-crystalline phase, or by structuring, e.g. by laser ablation.

The invention further provides electronic components comprising the compounds and mixtures of the invention as semiconductors.

The following examples serve to illustrate the invention and do not constitute a limitation.

### EXAMPLES

The compounds according to the invention of the formula (Z) can, for example, be prepared by methods analogous to the synthesis described below.

All reaction vessels were baked using the conventional protective gas technique and flooded with nitrogen before use.

### OFET Preparation:

### a) Substrate for OFET and Cleaning

p-doped silicon wafers which had been polished on one side and had a thermally grown oxide layer having a thickness of 300 nm (Sil-Chem) were cut into 25 mm×25 mm substrates. The substrates were firstly carefully cleaned. The adhering silicon splinters were removed by rubbing with a clean room cloth (Bemot M-3, Ashaih Kasei Corp.) under flowing distilled water and the substrates were subsequently cleaned in an aqueous 2% strength water/Mucasol solution at 60° C. in an ultrasonic bath for 15 minutes. The substrates were then rinsed with distilled water and spun dry in a centrifuge. Immediately before coating, the polished surface was cleaned in a UV/ozone reactor (PR-100, UVP Inc., Cambridge, GB) for 10 minutes.

### b) Dielectric Layer

i. Octyldimethylchlorsilane (ODMC) (Aldrich, 246859) was used as dielectric intermediate layer. The ODMC was poured into a Petri dish so that the bottom is just covered. The magazine in which the cleaned Si substrates standing upright on edge were present was then placed thereon. The whole was covered with an upturned glass beaker and the Petri dish was heated to 70° C. The substrates remained in the octyldimethylchlorsilane-rich atmosphere for 15 minutes.
ii. Hexamethyldisilazane (HMDS): The hexamethyldisilazane used for the dielectric intermediate layer (Aldrich, 37921-2) was poured into a glass beaker in which the magazine with the cleaned Si substrates standing upright on edge was located. The silazane covered the substrates completely. The glass beaker was covered and heated to 70° C. on a hot plate. The substrates remained in the silazane for 24 hours. The substrates were subsequently dried in a stream of dry nitrogen.

### c) Organic Semiconductors

To apply the semiconducting layer, a solution of the compounds in a suitable solvent was prepared. To achieve complete dissolution of the components, the solution was placed in an ultrasonic bath at 60° C. for about 1 minute. The concentration of the solution was 0.3% by weight.

The substrate provided with the dielectric intermediate layer was laid with the polished side facing upwards in the holder of a spin coating apparatus (Carl Süss, RC8 mit Gyrset®) and heated to about 70° C. by means of a hairdryer. About 1 ml of the still warm solution were dripped onto the surface and the solution containing the organic semiconductor was spun off from the substrate at 1200 rpm for 30 seconds at an acceleration of 500 revolutions/sec² and with the Gyrset® open.

### d) Application of the Electrodes

The electrodes for source and drain were subsequently vapour deposited onto this layer. This was carried out using a mask comprising an electrochemically produced Ni sheet having four recesses comprising two intermeshing combs. The teeth of the individual combs had a width of 100 μm and a length of 4.7 mm. The mask was placed on the surface of the coated substrate and fixed from the rear side by means of a magnet.

Gold was vapour deposited onto the substrates in a vapour deposition unit (Univex 350, Ley-bold).

### e) Capacity Measurement

The electrical capacity of the arrangements was determined by subjecting an identically prepared substrate but without organic semiconductor layer to vapour deposition, parallel behind identical masks. The capacitance between the p-doped silicon wafer and the vapour-deposited electrode was determined by means of a multimeter, MetraHit 18S, Gossen Metrawatt GmbH. The measured capacitance for this arrangement was C=0.7 nF, corresponding, on the basis of the electrode geometry, to a capacitance per unit area of C=6.8 nF/cm².

### f) Electrical Characterization

The characteristic curves were measured by means of two current-voltage sources (Keithley 238). The one voltage source applies an electric potential to source and drain and determines the current which flows, while the second voltage source applies an electric potential to gate and source. Source and drain are contacted with printed-on Au strips; the highly doped Si wafer formed the gate electrode and was contacted via the rear side from which the oxide had been scraped. The recording of the characteristic curves and their evaluation were carried out by the known methods, as described, for example, in “Organic thin-film transistors: A review of recent advances”, C. D. Dimitrakopoulos, D. J. Mascaro, IBM J. Res. & Dev. Vol. 45 No. 1 Jan. 2001.

### EXAMPLES

The syntheses were carried out under protected gas. For this purpose, all glass apparatuses were dried at 150° C. in an oven for 2 hours, assembled hot, evacuated and subsequently filled with protective gas. The solvents used were dried and degassed by standard methods.

### Example 1

### 1-(2,2′-bithien-5-yl)heptan-1-one

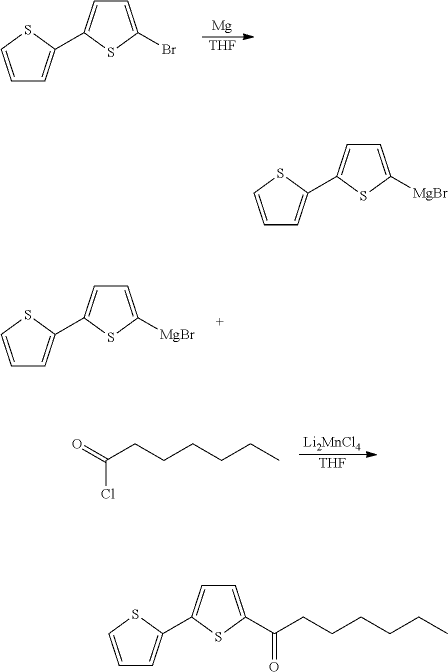

A solution of 5-bromo-2,2′-bithiophene (10.5 g, 42.8 mmol) in 110 ml of anhydrous THF was added dropwise to a suspension of magnesium (1.04 g, 43.7 mmol) in 10 ml of anhydrous THF. The mixture was subsequently refluxed for 2 hours. The cooled solution was then added dropwise to a solution of heptanoyl chloride (6.34 g, 34 mmol) and freshly prepared Li₂MgCl₄ (1.07 mmol, from 135 mg (1.07 mmol) of MnCl₂ and 95 mg (2.24 mmol) of LiCl in 15 ml of anhydrous THF) at 0° C. The mixture was subsequently warmed to room temperature over a period of 2 hours and stirred for another 1 hour. The solution was poured into 400 ml of water and 600 ml of diethyl ether. The organic phase was separated off, washed with water, dried over sodium sulphate, filtered and the solvent was evaporated under reduced pressure. This gave 12.1 g of crude product which were purified by chromatography over silica gel (eluent toluene-hexane 1:1) to give 10.70 g (94%) of product.

¹H NMR (250 MHz, CDCl₃, δ, ppm): 0.88 (t, 3H, J=6.7 Hz, —CH₂—CH₃), 1.20-1.45 (overlapping peaks, 6H, —CH₂—CH₂—CH₂—), 1.73 (m, 2H, M=5, J=7.3 Hz, —CH₂—CH₂—CH₂—CO—), 2.85 (t, 2H, J=7.3 Hz, —CH₂—CH₂—CO—), 7.15 (d, 1H, J=3.7 Hz), 7.30 (s, 1H), 7.28-7.33 (overlapping peaks, 2H), 7.58 (d, 1H, J=4.3 Hz).

### Example 2

### 2-(2,2′-bithien-5-yl)-2-hexyl-1,3-dioxolane

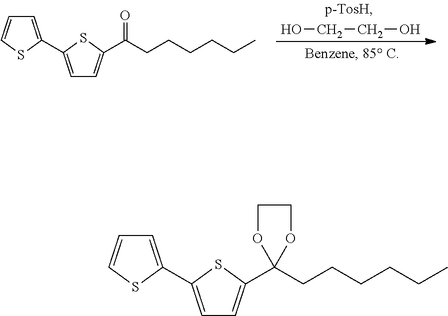

1-(2,2′-bithien-5-yl)heptan-1-one (10.0 g, 35.9 mmol) was dissolved in hot benzene (350 ml) and admixed with p-toluenesulfonic acid (1.37 g, 7.2 mmol) and ethylene glycol (80 ml, 89 g, 1.44 mol). The solution was boiled at 115° C. for 18 hours on a water separator. The solution was subsequently washed with saturated sodium-hydrogencarbonate solution, the organic phase was separated off, dried over sodium sulphate, filtered and the solvent was evaporated under reduced pressure. This gave 11.79 g of crude product which were purified by chromatography over silica gel (eluent toluene) and recrystallization from hexane. This gave 8.35 g (72%) of product.

¹H NMR (250 MHz, CDCl₃, δ, ppm): 0.87 (t, 3H, J=6.7 Hz, —CH₂—CH₃), 1.20-1.48 (overlapping peaks, 6H, —CH₂—CH₂—CH₂—), 1.40 (m, 2H, M=5, J=7.3 Hz, —CH₂—CH₂—CH₂—C(O—CH₂—CH₂—O)—), 1.99 (t, 2H, J=7.3 Hz, —CH₂—CH₂—C(O—CH₂—CH₂—O)—), 4.00 (m, 4H, CH₂—C(O—CH₂—CH₂—O)-T), 6.88 (d, 1H, J=3.7 Hz), 6.99 (dd, 1H, J₁=4.9 Hz, J₂=3.7 Hz), 7.00 (d, 1H, J=3.7 Hz), 7.12 (dd, 1H, J₁=3.7 Hz, J₂=1.2 Hz), 7.19 (dd, 1H, J₁=5.4 Hz, J₂=1.2 Hz).

### Example 3

### 1-[5′-(4,4,5,5-tetramethyl-1,3,2-dioxaborolan-2-yl)-2,2′-bithien-5-yl]-2-hexyl-1,3-dioxolane

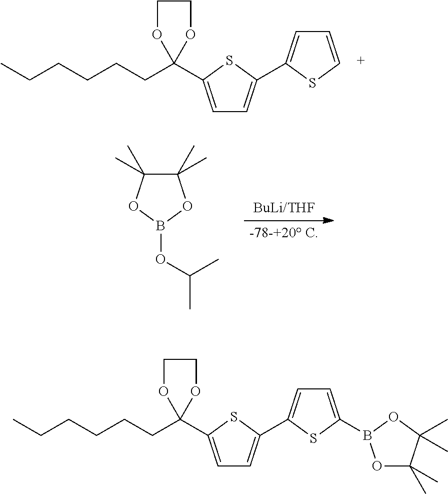

A 1.6 M solution of butyllithium (15.70 ml, 25.1 mmol) in hexane were added dropwise to a solution of 2-(2,2′-bithien-5-yl)-2-hexyl-1,3-dioxolane (8.10 g, 25.1 mmol) in 250 ml of anhydrous THF at from −70 to −75° C. The reaction solution was stirred at −75° C. for another 60 minutes and 2-isopropoxy-4,4,5,5-tetramethyl-1,3,2-dioxaborolane (5.124 ml, 25.1 mmol) were subsequently added all at once. The solution was stirred at −78° C. for another 1 hour and at room temperature for a further hour. 600 ml of freshly distilled diethyl ether and 300 ml of degassed water were added. 25 ml of a 1 M HCl were added dropwise while stirring. The organic phase was separated off, washed with water, dried over sodium sulfate, filtered and the solvent was evaporated under reduced pressure. This gave 11.26 g (95%) of product.

¹H NMR (250 MHz, CDCl₃, δ, ppm): 0.84 (t, 3H, J=6.7 Hz, —CH₂—CH₃), 1.20-1.48 (overlapping peaks with maximum at 1.33 ppm, 20H, —CH₂—CH₂—CH₂— and O—C(CH₃)₂), 1.99 (t, 2H, J=7.3 Hz, —CH₂—CH₂—C(O—CH₂—CH₂—O)—), 4.00 (m, 4H, CH₂—C(O—CH₂—CH₂—O)-T), 6.88 (d, 1H, J=3.7 Hz), 7.06 (d, 3H, J=3.7 Hz), 7.18 (d, 1H, J=3.7 Hz), 7.49 (d, 1H, J=3.7 Hz).

### Example 4

### 1-[5′-(4,4,5,5-tetramethyl-1,3,2-dioxaborolan-2-yl)-2,2′-bithien-5-yl]heptan-1-one

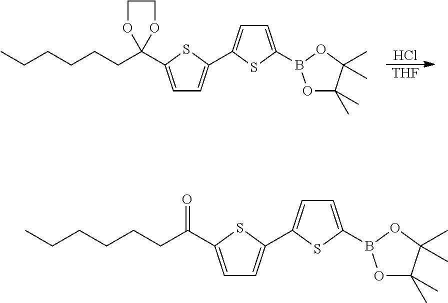

1-[5′-(4,4,5,5-tetramethyl-1,3,2-dioxaborolan-2-yl)-2,2′-bithien-5-yl]-2-hexyl-1,3-dioxolane (5.1 g, 11.40 mmol) were dissolved in anhydrous THF (50 ml) and admixed with 1.14 ml (1.1 mmol) of concentrated HCl. The solution was stirred at room temperature for 7 hours. 400 ml of freshly distilled diethyl ether and 200 ml of degassed water were subsequently added. The organic phase was separated off, washed with saturated aqueous NaHCO₃ solution, dried over sodium sulfate, filtered and the solvent was evaporated under reduced pressure. This gave 4.2 g (96%) of product.

¹H NMR (250 MHz, CDCl₃, δ, ppm): 0.88 (t, 3H, J=6.7 Hz, —CH₂—CH₃), 1.20-1.45 (overlapping peaks with maximum at 1.34 ppm, 18H, —CH₂—CH₂—CH₂— and O—C(CH₃)₂), 1.73 (m, 2H, M=5, J=7.3 Hz, —CH₂—CH₂—CH₂—CO—), 2.85 (t, 2H, J=7.3 Hz, —CH₂—CH₂—CO—), 7.20 (d, 1H, J=3.7 Hz), 7.35 (d, 1H, J=3.7 Hz), 7.53 (d, 1H, J=3.7 Hz), 7.59 (d, 1H, J=4.3 Hz).

### Example 5

### 1-(5′-bromo-2,2′-bithien-5-yl)undec-10-en-1-one

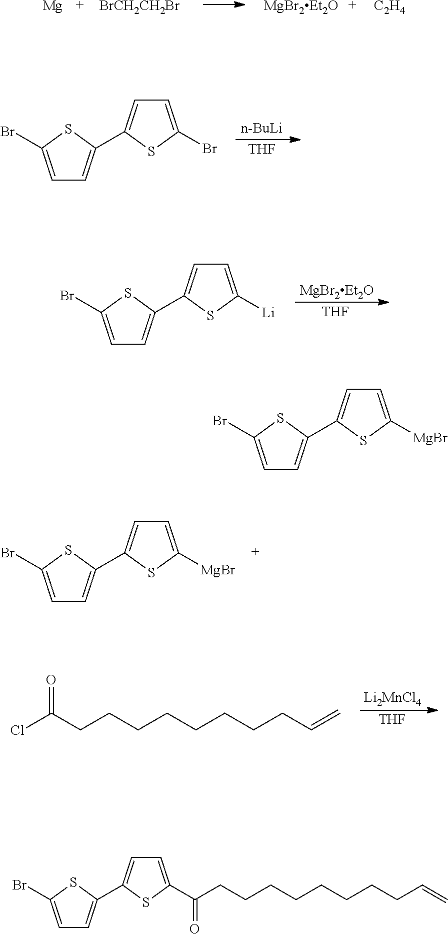

Step 1. Synthesis of magnesium bromide-diethyl ether complex. A suspension of magnesium (969 mg, 38.6 mmol) in 15 ml of anhydrous THF was added dropwise to a solution of 1,2-dibromoethane (3.18 ml, 36.7 mmol) in 25 ml of diethyl ether. The reaction mixture was refluxed for 30 minutes, subsequently cooled to room temperature and used further in step 2.

Step 2. Preparation of (5′-bromo-2,2′-bithien-5-yl)magnesium bromide. A 1.6 M solution of butyllithium (19.3 ml, 30.9 mmol) in hexane was added dropwise to a solution of 5,5′-dibromo-2,2′-bithiophene (10.00 g, 30.9 mmol) in 450 ml of anhydrous THF at −40° C. The reaction mixture was subsequently stirred at −40° C. for 30 minutes. The magnesium bromide-diethyl ether complex solution from step 1 was then added all at once. The reaction solution was stirred further at −40° C. for 30 minutes and subsequently at room temperature for 2 hours.

Step 3. Preparation of 1-(5′-bromo-2,2′-bithien-5-yl)undec-10-en-1-one. The Grignard solution from step 2 was added dropwise to a solution of undecenoyl chloride (6.26 g, 30.9 mmol) and a freshly prepared solution of Li₂MgCl₄ (1.54 mmol) in anhydrous THF at −5° C. (Li₂MgCl₄ was prepared from MnCl₂ (194 mg, 15.4 mmol) and LiCl (137 mg, 32.4 mmol) by stirring these in 50 ml of anhydrous THF at room temperature for 2 hours.) The mixture was warmed to room temperature over a period of 2 hours and stirred for a further hour.

The reaction solution was subsequently poured into 400 ml of water and stirred with 600 ml of diethyl ether. The organic phase was separated off, washed with water, dried over sodium sulfate, filtered and the solvent was taken off under reduced pressure. This gave 12.06 g of crude product which was purified by repeated recrystallization from toluene and chromatography over silica gel (eluent: toluene-hexane 1:1, 60° C.). This gave 8.89 g (63%) of product in the form of orange crystals.

¹H NMR (250 MHz, CDCl₃, δ, ppm): 1.20-1.45 (overlapping peaks, 10H, —CH₂—CH₂—CH₂—), 1.72 (m, 2H, M=5, J=7.3 Hz, —CH₂—CH₂—CH₂—CO—), 2.02 (dt, 2H, J₁=7.3 Hz, J₂=7.1 Hz, —CH₂—CH₂—CH═CH₂), 2.82 (t, 2H, J=7.5 Hz, —CH₂—CH₂—CO—), 4.95 (m, 2H, —CH₂—CH═CH₂), 5.78 (m, 1H, —CH₂—CH═CH₂), 7.00 (d, 1H, J=3.7 Hz), 7.05 (d, 1H, J=3.7 Hz), 7.09 (d, 1H, J=4.3 Hz), 7.30 (s, 1H), 7.57 (d, 1H, J=4.3 Hz).

### Example 6

### 1-(5′″-heptanoyl-2,2′:5′,2″:5″,2′″-quaterthien-5-yl)undec-10-en-1-one

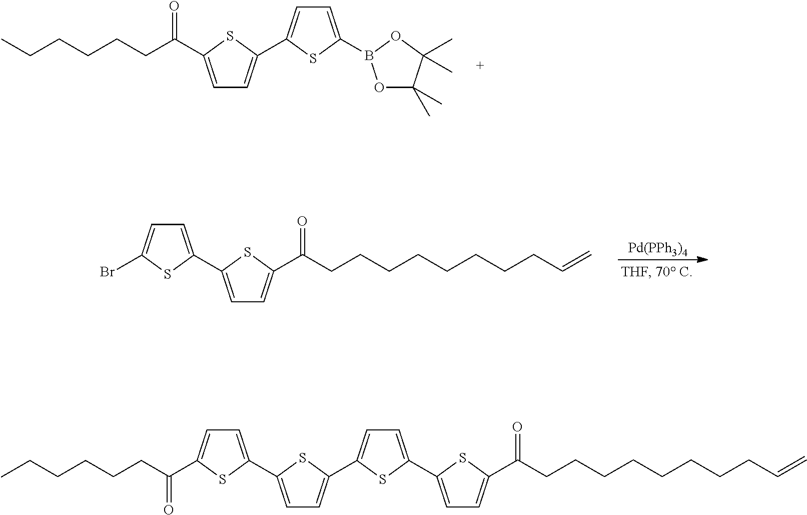

A solution of 3.26 g (8.07 mmol) of 1-[5′-(4,4,5,5-tetramethyl-1,3,2-dioxaborolan-2-yl)-2,2′-bithien-5-yl]heptan-1-one and 2.79 g (6.78 mmol) of 1-(5′-bromo-2,2′-bithien-5-yl)undec-10-en-1-one in 120 ml of toluene was degassed and admixed with 466 mg of Pd(PPh₃)₄. 24 ml of an aqueous, degassed 2M Na₂CO₃ solution were subsequently added and the reaction mixture was stirred under reflux for 12 hours. 300 ml of toluene and 300 ml of water were added, the organic phase was separated off, washed with water until it was pH neutral, dried, filtered and the solvent was taken off under reduced pressure. The crude product was recrystallized from toluene. This gave 4.07 g (99%) of product.

¹H NMR (250 MHz, CDCl₃, δ, ppm): 0.90 (t, 3H, J=6.7 Hz, —CH₂—CH₃), 1.22-1.45 (overlapping peaks, 16H, —CH₂—CH₂—CH₂—), 1.78 (m, 4H, M=5, J=7.3 Hz, —CH₂—CH₂—CH₂—CO—), 2.01 (m, 2H, M=4, J=6.7 Hz, —CH₂—C═CH₂), 2.85 (t, 4H, J=7.3 Hz, —CH₂—CH₂—CO—), 4.95 (m, 2H, —CH₂—CH═CH₂), 5.78 (m, 1H, —CH₂—CH═CH₂), 7.14 (d, 2H, J=3.7 Hz), 7.17 (d, 2H, J=4.3), 7.22 (d, 2H, J=3.7 Hz), 7.58 (d, 2H, J=4.3 Hz).

### Example 7

### {1-[5′″-(2,2-dicyano-1-hexylvinyl)-2,2′:5′,2″:5″,2′″-quaterthien-5-yl]undec-10-en-1-ylidene}malononitrile

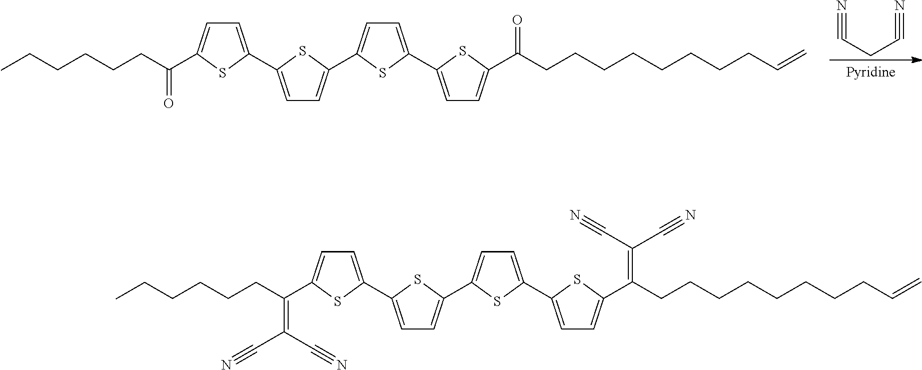

2.5 g (4.1 mmol) of 1-(5′-heptanoyl-2,2′:5′,2″:5″,2′″-quaterthien-5-yl)undec-10-en-1-one, 1.08 g (16.4 mmol) of malononitrile and 120 ml of anhydrous pyridine were stirred at 90° C. for 25 hours. The solvent was subsequently removed under reduced pressure and the crude product obtained was purified by chromatography (silica gel, eluent: toluene-THF 10:1). This gave 1.48 g (51%) of pure product.

¹H NMR (250 MHz, CDCl₃, δ, ppm): 0.89 (t, 3H, J=6.7 Hz), 1.22-1.42 (overlapping peaks, 12H, —CH₂—CH₂—CH₂), 1.46 (m, 4H, M=5, J=7.3 Hz, —CH₂—CH₂—CH₂—C(CN)₂—), 1.70 (m, 4H, M=5, J=7.3 Hz, —CH₂—CH₂—C(CN)₂—), 2.02 (m, 2H, M=4, J=6.7 Hz, —CH₂—C═CH₂), 2.93 (t, 4H, J=7.3 Hz, —CH₂—C(CN)₂—), 4.95 (m, 2H, —CH₂—CH═CH₂), 5.78 (m, 1H, —CH₂—CH═CH₂), 7.20 (d, 2H, J=4.3), 7.28 (d, 2H, J=4.3), 7.31 (d, 2H, J=4.3), 7.95 (d, 2H, J=3.7).

### Example 8

### [1-[5′″-(2,2-dicyano-1-hexylvinyl)-2,2′:5′,2″:5″,2′″-quaterthien-5-yl]-11-(1,1,3,3-tetramethyldisiloxanyl)undecylidene]malononitrile

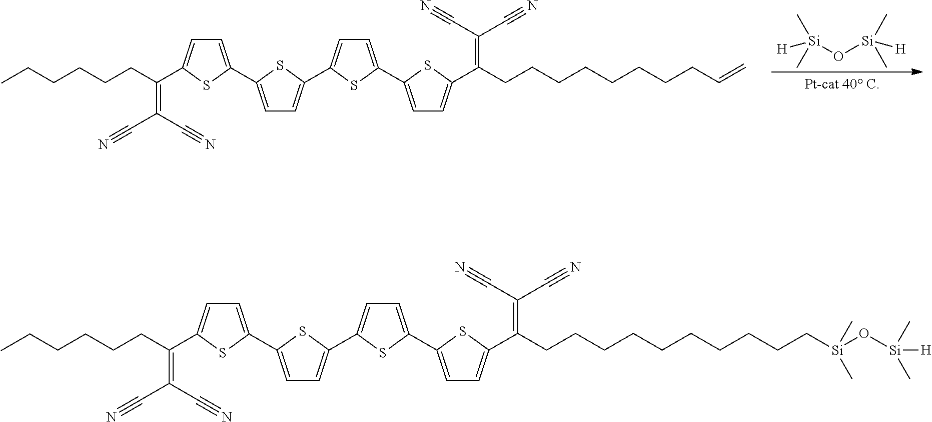

0.24 g (0.34 mmol) of {1-[5′″-(2,2-dicyano-1-hexylvinyl)-2,2′:5′,2″:5″,2′″-quaterthien-5-yl]undec-10-en-1-ylidene}malononitrile and 10 ml of 1,1,3,3-tetramethyldisiloxane were dissolved in 20 ml of toluene at 40° C. 30 μL of a 0.1 M solution of Karstedt's catalyst in xylene were subsequently added. The reaction solution was stirred at 40° C. for 2 hours. The excess 1,1,3,3-tetramethyldisiloxane was subsequently taken off together with the toluene under reduced pressure. The crude product obtained (0.27 g) comprising 72% of product, 8.5% of the dimer and 19% of starting material with a shifted double bond was reacted further without purification.

### Example 9

### 1,3-bis-{3-[5′″-(2,2-dicyano-1-hexylvinyl)-2,2′:5′,2″:5″,2′″-quaterthien-5-yl]-undecylidene]malononitrile}-1,1,3,3-tetramethyldisiloxane

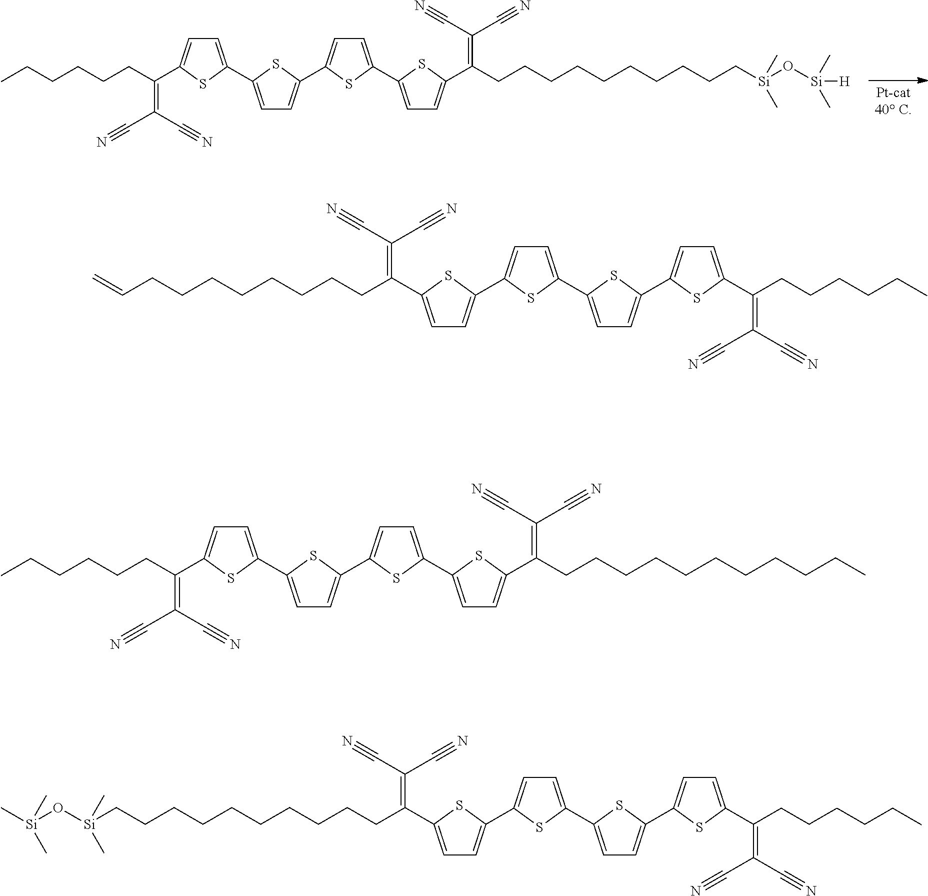

[1-[5′″-(2,2-dicyano-1-hexylvinyl)-2,2′:5′,2″:5″,2′″-quaterthien-5-yl]-11-(1,1,3,3-tetramethyldisiloxanyl)undecylidene]malononitrile (0.25 g, 0.3 mmol) and {1-[5′″-(2,2-dicyano-1-hexylvinyl)-2,2′:5′,2″:5″,2′″-quaterthien-5-yl]undec-10-en-1-ylidene}malononitrile (0.27 g, 0.39 mmol) were dissolved in 15 ml of anhydrous toluene at 40° C. and subsequently admixed with 20 μL of a 0.1 M solution of Karstedt's catalyst in xylene. The reaction mixture was stirred at 40° C. for 6 hours. The solvent was subsequently removed under reduced pressure. This gave 0.52 g of product containing 56% of the desired product.

1.-11. (canceled)

12. A macromolecular compound which comprises a core-shell structure, wherein the core has a macromolecular base structure based on silicon and/or carbon and is joined to at least two carbon-based linear oligomeric chains having continuously conjugated double bonds via a connecting chain based on carbon and wherein the linear conjugated chains are each capped via at least one methylene carbon atom bearing an electron-withdrawing group by at least one further, in particular aliphatic, araliphatic or oxyaliphatic chain without conjugated double bonds.

13. The compound according to claim 12, wherein the macromolecular compound(s) having a core-shell structure are compounds of the formula (Z), 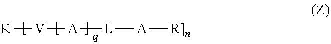
where
K is an n-functional core,
V is a connecting chain,
L is a linear conjugated oligomeric chain,
A is a methylene carbon atom bearing electron-withdrawing groups which is selected from the group consisting of carbonyl, dicyanovinyl, cyanoacrylic esters, malonic esters and dihalomethylene,
R stands for linear or branched C₂-C₂₀-alkyl radicals, C₃-C₈ cycloalkylene radicals, monounsaturated or polyunsaturated C₂-C₂₀-alkenyl radicals, C₂-C₂₀-alkoxy radicals, C₂-C₂₀-aralkyl radicals or C₂-C₂₀-oligoether or C₂-C₂₀-polyether radicals,
q is 0 or 1 and
n is an integer greater than or equal to 2.

14. The compound according to claim 13, wherein
L is an optionally substituted thiophene or phenylene units, and
n is an integer between 2 and 4.

15. The compound according to claim 12, wherein the core of the macromolecular compound(s) has a dendritic or hyperbranched structure.

16. The compound according to claim 12, wherein the dendritic core of the macromolecular compound(s) comprises siloxane and/or carbosilane units.

17. The compound according to claim 12, wherein the connecting chains V are linear or branched C₂-C₂₀-alkylene chains, linear or branched polyoxyalkylene chains, linear or branched siloxane chains and/or linear or branched carbosilane chains.

18. The compound according to claim 12, wherein the shell of the macromolecular compound(s) comprises oligothiophene chains and/or oligo(3,4-ethylenedioxythiophene) chains having from 2 to 8 optionally substituted thiophene and/or 3,4-ethylenedioxythiophene units as linear conjugated oligomeric chains.

19. The compound according to claim 12, wherein the linear conjugated oligomeric chains of the macromolecular compound(s) are capped at each of the terminal linkage positions by identical or different, branched or unbranched alkyl or alkoxy groups.

20. The compound according to claim 12, wherein the linear conjugated oligomeric chains of the macromolecular compound(s) are capped at each of the terminal linkage positions by identical or different, branched or unbranched alkyl.

21. A semiconductor in electronic components which comprises the compound according to claim 12.

22. An electronic component comprising the compound according to claim 12 as semiconductor.

23. The electronic component as claimed in claim 22, wherein the component is a field effect transistor, a light-emitting component, a photovoltaic cell, a laser or a sensor.

24. The electronic component as claimed in claim 22, wherein the component is an organic light-emitting diode.

25. A process for preparing a component which comprises applying the compound as claimed in claim 12, in the form of layers from solutions to the component.
